(19) United States
(12) Patent Application Publication
(10) Pub. No.: US 2006/0175686 A1
(43) Pub. Date: Aug. 10, 2006

(54) Semiconductor device and fabrication method thereof

(75) Inventors: Koichi Murata, Kawasaki (JP); Masamitsu Ikumo, Kawasaki (JP); Eiji Watanabe, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/150,252

(22) Filed: Jun. 13, 2005

(30) Foreign Application Priority Data
Feb. 9, 2005 (JP) 2005-033548

(51) Int. Cl. H01L 23/58

(52) U.S. Cl. 257/642

(57) ABSTRACT

A semiconductor device fabrication method comprises the steps of: (a) forming a pad electrode on the semiconductor device; (b) coating the surface of the semiconductor device with an organic dielectric film so as to expose the center portion of the pad electrode; (c) treating the exposed surface of the pad electrode by dry etching; and (d) removing an altered layer produced in the organic dielectric film due to the dry etching for the surface treatment, using an oxygen-free dry process.

### BACKGROUND OF THE INVENTION

1. Field of the Invention

The present invention generally relates to a semiconductor device with bump electrodes (or protruding electrodes) and a fabrication method thereof, and more particularly, to removal of an altered layer generated in the surface area of an organic dielectric due a dry etching process for native oxide removal from a metal surface (such as a metal pad), in order to prevent surface leakage.

2. Description of the Related Art

Providing protruding electrodes or bump electrodes on a semiconductor device, such as an IC chip, has become mainstream, which technique allows the chip to be mounted directly on a substrate. In recent years and continuing, the bump pitch becomes narrower and narrower along with the miniaturization of the semiconductor devices and the packages.

A bump is formed on a pad electrode to provide electric connection with internal electrodes. In general, the surface of a semiconductor device is covered with a passivation film, and then coated with an organic dielectric, such as a polyimide coating film for the purpose of device protection. An opening is formed in the organic dielectric and the passivation film so as to expose the pad surface. Prior to forming a seed layer on the exposed pad surface, dry etching (RF etching) is performed, as pretreatment, using argon (Ar) gas in order to remove the native oxide layer from the pad surface.

During the dry etching, the film quality of the surface area of the organic dielectric is altered, and the electrical isolation ability of the organic coat is degraded due to the altered layer. To overcome this problem, it is proposed to remove the altered layer by performing O2 ashing using a microwave (MW) asher or an RF asher, after the bump electrodes are fabricated. See, for example, JP 10-56020A and JP 7-130750A.

FIG. 1 illustrates how a polyimide altered layer is removed with a conventional technique. An aluminum (Al) or aluminum-alloy pad 101 is formed on a semiconductor wafer 110 via a dielectric layer 111. The pad 101 is electrically connected to an internal electrode, such as a gate electrode (not shown).

An opening 108 is formed in passivation film 102 and polyimide film 103 so as to expose the center of the pad 101. To remove the native oxide layer (not shown) from the exposed surface of the pad 101, dry etching is performed using argon ions. Due to the influence of the dry etching, an altered layer 104 is generated in the surface area of the polyimide film 103.

Then, a titanium (Ti) film 105 and a copper (Cu) film 106 are deposited successively over the pad 101 from which the native oxide film has been removed, as well as over the polyimide layer 103 (including the altered layer 104), by sputtering. A resist mask (not shown) with a prescribed pattern is provided to form a bump electrode 107 on the copper (Cu) film 106. Then, the resist mask is removed, and unnecessary portions of the Cu film 106 and the Ti film 105 are removed using the bump electrode 107 as a mask. Then, microwave (MW) ashing is performed using O2 gas to remove the polyimide altered layer 104 located between bump electrodes 107.

Removal of the native oxide layer from conductive surfaces surrounded by an organic dielectric is often performed, other than pad surfaces. If a dry process is employed to remove the native oxide layer, an altered layer is generated over the organic dielectric film. For example, when fabricating a copper (Cu) interconnection electrically connected to the pad electrode on an interposer or a redistribution layer, or when forming a contact hole for electric connection between upper-level and lower-level interconnections, a conductive surface is exposed in the opening or the contact hole. Due to the influence of plasma etching for removing the native oxide layer from the conductive surface, the top face of the inter-level organic dielectric is degraded or altered. It is proposed in WO 99/38208 to remove the altered layer of the interlevel organic dielectric in a multi-level wiring board by photoexcited ashing using O2 gas, oxygen radicals, or ozone.

The conventional method shown in FIG. 1 for removing the altered or degraded layer of an organic dielectric is based on the premise that a gold (Au) plated bump of a TAB (tape automated bonding) type is used. Since gold (Au) is a stable metal, the bump surface is hardly oxidized during the O2 ashing. However, with the method shown in FIG. 1, the etching rate with respect to polyimide is low, and therefore, the altered layer cannot be removed completely. For this reason, leakage occurs at resistance of about 1.0*10⁶ Ω. It is inferred that the bumps may function as lightning arresters to cause the etching rate to fall. Especially when the electrode 107 is formed in the form of a bump or an under-bump metal (UBM) positioned higher than the polyimide layer 102, it becomes difficult to remove the polyimide altered layer 103 between adjacent pads.

Another problem with the conventional method shown in FIG. 1 is that this technique is unsuitable for soldering bumps or copper (Cu) interconnections. If O2 ashing is performed to remove the altered layer after solder bumps are formed, the bump surface is oxidized, and fragments of the oxide fly onto the surface of the organic dielectric (such as the polyimide layer). In addition, microwave plasma etching generally degrades the surface of the polyimide layer, causing tarnish on it.

### SUMMARY OF THE INVENTION

To overcome the above-described problem, it may be proposed to form a slit 109 in the polyimide layer 103 in advance in order to guarantee separation of the electrodes, as illustrated in FIG. 2. With this arrangement, even if the quality of the surface area of the polyimide layer 103 is altered, producing the altered layer 104 due to the dry etching for native oxide removal, leakage can be prevented owing to the existence of the slit 109.

However, as the bump pitch becomes narrower, it becomes more difficult to guarantee a sufficient area for defining the slit 109. In addition, the side edges of the passivation film 102 and the polyimide layer 103 are exposed in the slit 109. Since the adhesion of the passivation film 102 to the underfill material is different from that of the polyimide layer 103, it becomes difficult to maintain uniformity in the assembling process.

Therefore, it is an object of the present invention to provide a technique for removing the altered layer on an organic dielectric efficiently, while preventing tarnish on the organic coating.

It is also an object of the present invention to provide a semiconductor device with reliable performance with reduced surface leakage.

To achieve the objects of the invention, the altered layer generated on the organic dielectric of a semiconductor device is removed without using O2 ashing.

In one aspect of the invention, a semiconductor device using an organic dielectric layer with less damage on it is provided. The semiconductor device comprises:

(a) a pad electrode arranged at a prescribed position on a semiconductor wafer;

(b) an organic dielectric film that covers the semiconductor wafer, leaving a center portion of the pad electrode uncovered;

(c) an altered layer located in the surface area of the organic dielectric film; and

(d) a conductor connected to the pad electrode;

wherein an altered layer removed region is provided so as to separate the conductor from an adjacent one, and the organic dielectric film is overetched in the altered layer removed region at an overetch depth of 10 nm to 100 nm.

In the second aspect of the invention, a method for fabricating a semiconductor device in which a portion of the altered layer generated in the surface area of an organic dielectric layer is removed is provided. The method includes the steps of:

(a) forming a pad electrode on the semiconductor device;

(b) coating the surface of the semiconductor device with an organic dielectric film so as to expose the center portion of the pad electrode;

(c) treating the exposed surface of the pad electrode by dry etching; and

(d) removing an altered layer produced in the organic dielectric film due to the dry etching for the surface treatment, using an oxygen-free dry process.

By not using oxygen, oxidization of the conductor surface can be prevented during the removal of the altered layer.

In a preferred example, the oxygen-free dry process is radio frequency (RF) plasma etching under oxygen-free gas supply.

Oxygen-free RF plasma etching allows the altered layer to be removed efficiently, while preventing surface degradation, such as tarnish, of the organic dielectric film during the removal of the altered layer.

### BRIEF DESCRIPTION OF THE DRAWINGS

Other objects, features, and advantages of the present invention will become more apparent from the following detailed description when read in conjunction with the accompanying drawings, in which:

FIG. 1 is a diagram for explaining a conventional method for removing a polyimide altered layer;

FIG. 2 is a diagram illustrating a proposal for forming a slit in the polyimide altered layer and the passivation film to electrically separate adjacent electrodes;

FIG. 3A through FIG. 3F illustrate a semiconductor device fabrication process according to the first embodiment of the invention;

FIG. 4A through FIG. 4G illustrate a modification of the semiconductor device fabrication process of the first embodiment;

FIG. 5A through FIG. 5G illustrates a semiconductor device fabrication process according to the second embodiment of the invention;

FIG. 6A through FIG. 6C illustrate the steps following the step of FIG. 5D, showing a modification of the semiconductor device fabrication process of the second embodiment;

FIG. 7A through FIG. 7D illustrate the steps following the step of FIG. 5D, showing another modification of the semiconductor device fabrication process of the second embodiment;

FIG. 8A through FIG. 8F illustrate a semiconductor device fabrication process according to the third embodiment of the invention; and

FIG. 9A and FIG. 9B illustrate a semiconductor device fabrication process according to the fourth embodiment of the invention.

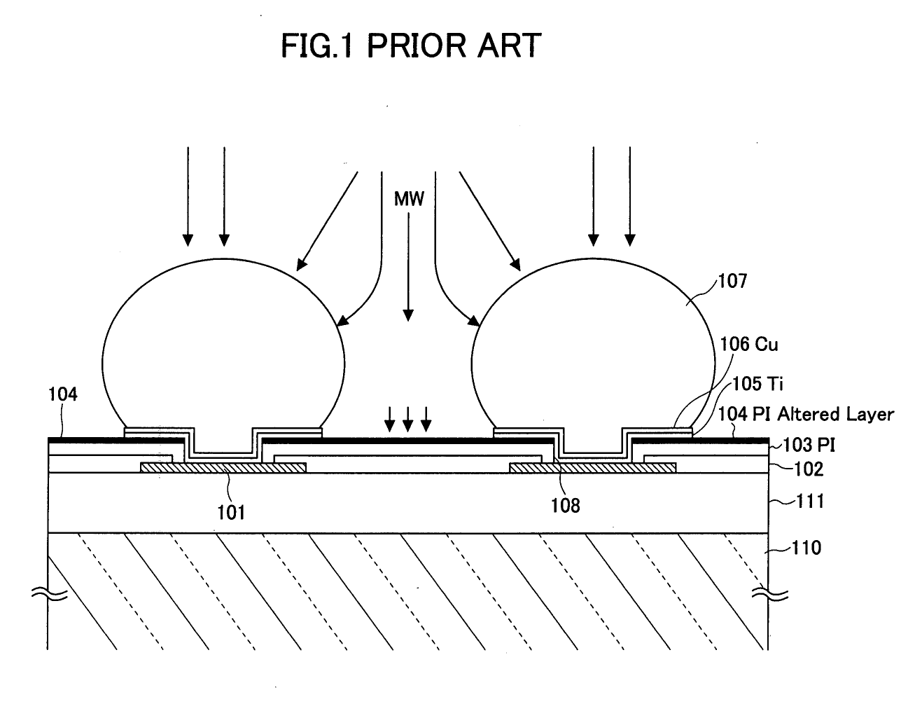

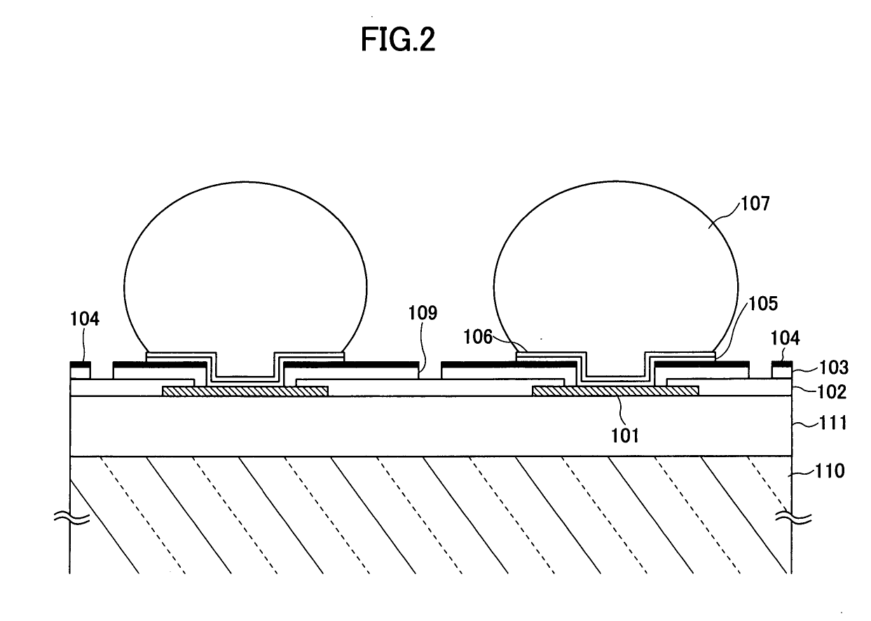

### DETAILED DESCRIPTION OF THE PREFERRED EMBODIMENTS

The preferred embodiments of the present invention are described below with reference to the attached drawings.

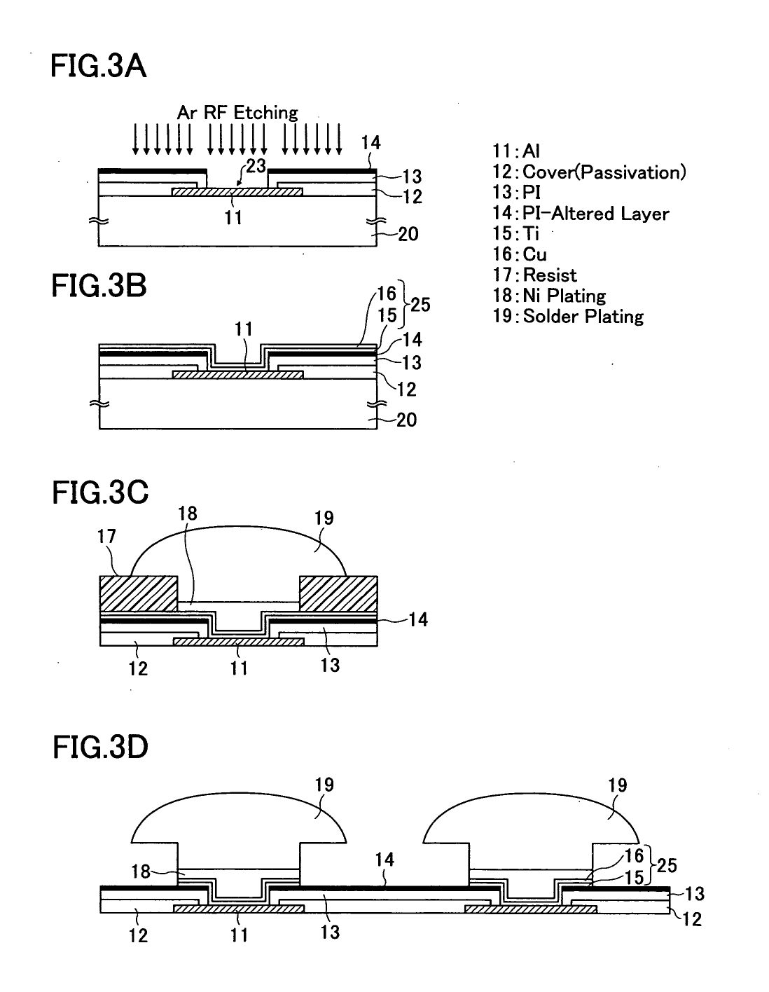

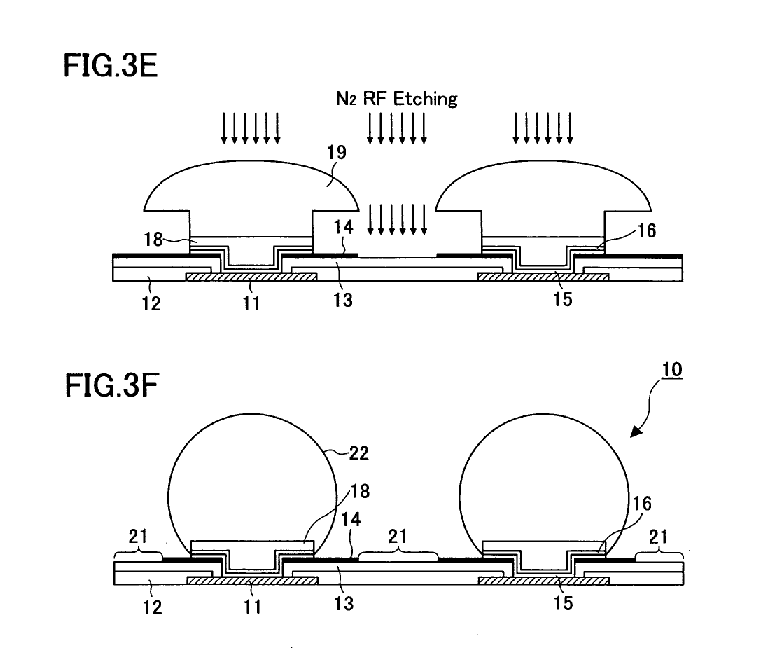

FIG. 3A through FIG. 3F illustrate a semiconductor device fabrication process according to the first embodiment of the invention.

First, as illustrated in FIG. 3A, aluminum (Al) pad 11 is formed at a prescribed position on a semiconductor wafer 20 in which internal circuits (not shown) are formed and covered with dielectric layers. The pad 11 provides electric connection with the internal circuit. The pad 11 and the entire surface of the semiconductor wafer 20 are covered with a passivation film (cover film) 12. An opening is formed in the passivation film 12 so as to expose the surface of the Al pad 11. Then, a photosensitive or nonphotosensitive polyimide overcoat (organic coat) 13 is formed over the exposed Al pad 11 and the passivation film 12. The thickness of the polyimide film 13 is 1 μm to 20 μm, depending on the design. A prescribed position of the polyimide film 13 is etched to form an opening 23 so as to expose the Al pad 11. Then, radio-frequency RF etching is performed as pretreatment prior to sputtering, using argon (Ar) gas, to remove the native oxide layer (not shown) from the exposed surface of the Al pad 11. During the dry etching, the surface area of the polyimide film 13 is altered, and the altered layer 14 is produced. In the altered layer 14, the resistance level falls down to 1.0*10⁴ Ω, and it serves as a leakage layer. Accordingly, the altered layer is to be removed in a later step.

Then, as illustrated in FIG. 3B, a titanium (Ti) film 15 and a copper (Cu) film 16 are formed successively by sputtering to form a seed layer 25.

Then, as illustrated in FIG. 3C, a resist 17 with an opening pattern at a position corresponding to the Al pad 11 is formed, and a nickel (Ni) film 18 and solder 19 are formed successively by plating. The solder 19 may be formed of an appropriate material, such as Sn/Cu, Sn/Ag, Sn/Ag/Cu, or Pb/Sn.

Then, as illustrated in FIG. 3D, the resist 17 is removed using, for example, an organic solvent. Unnecessary portions of the Cu film 16 and the Ti film 15 are also removed by wet etching, using the Ni plating film 18 as a mask.

Then, as illustrated in FIG. 3E, the altered layer 14 is removed from the region extending between adjacent solder plating layers 19 by nitrogen (N2) etching, using an etching/ashing apparatus (not shown) equipped with an RF power source of 13.56 MHz. The dry etching is performed for 60 seconds at power of 200 W, under the nitrogen (N2) gas supply of 500 sccm at gas pressure of 40 Pa. The process temperature is lower than or equal to the melting point of the solder. After the removal of the altered layer 14, the resistance level rises up to 1.0*10¹¹ Ω or higher, and the electric insulation of the polyimide film 13 is restored.

Then, as illustrated in FIG. 3F, reflow treatment is performed to form a bump 22, and a semiconductor device 10 is completed. In the altered layer 14 is formed a groove or a removed region 21 from which the altered layer 14 is removed by RF etching without using oxygen. The groove or the removed region 21 guarantees electrical separation between adjacent bumps 22.

In the first embodiment, radio-frequency (RF) etching is employed to remove the altered layer. RF plasma can reach the top face of the polyimide layer 13 even if the gap between adjacent electrodes is narrow. Accordingly, the altered layer 14 can be removed even after the formation of the solder plating layer 19.

In the example shown in FIG. 3E, the gap between the adjacent solder plating layers 19 is as narrow as about 10 μm to 20 μm; however, the altered layer 14 is removed in a reliable manner by employing RF etching. It is expected that the gap between adjacent solder plating layers 19 may become 10 μm or less along with the miniaturization of semiconductor devices. With the technique of the first embodiment, the altered layer 14 can be removed as long as there is a gap in the range from 2 μm to 100 μm.

It is necessary for the bump or protruding electrode 22 to have a certain height in order to avoid adverse influence, such as thermal stress, after the semiconductor device 10 is mounted on a mother board or a package board. The arrangement of the first embodiment allows the altered layer 14 to be removed by RF etching even if the narrow-pitched solder plating layers 19 have a height of 100 μm to 120 μm.

Since oxygen gas is not used during the RF etching, undesirable oxidation is prevented on the surface of the solder plating layer 19. This means that the removal of the altered layer 14 can be performed either before or after the reflow treatment.

During the removal of the altered layer 14, the top face of the polyimide film 13 is slightly overetched (not shown). Unlike microwave O2 ashing, the overetch depth is as small as 10 nm to 20 nm, and the assembling property is maintained satisfactory. Since the overetch depth of the polyimide film 13 may be varied in the range from 10 nm to 100 nm, which range allows the assembling property to be maintained good, the etching conditions can be appropriately adjusted in this range, depending on the height and gap of the solder plating layers 19.

Another advantage of RF etching is that surface degradation or tarnish of the polyimide surface, which is caused by microwave (MW) etching, can be prevented.

As the etching gas used to remove the altered layer 14, H2 gas, Ne gas, He gas, or combinations thereof (e.g., N2-H2) may be employed, other than nitrogen (N2) gas.

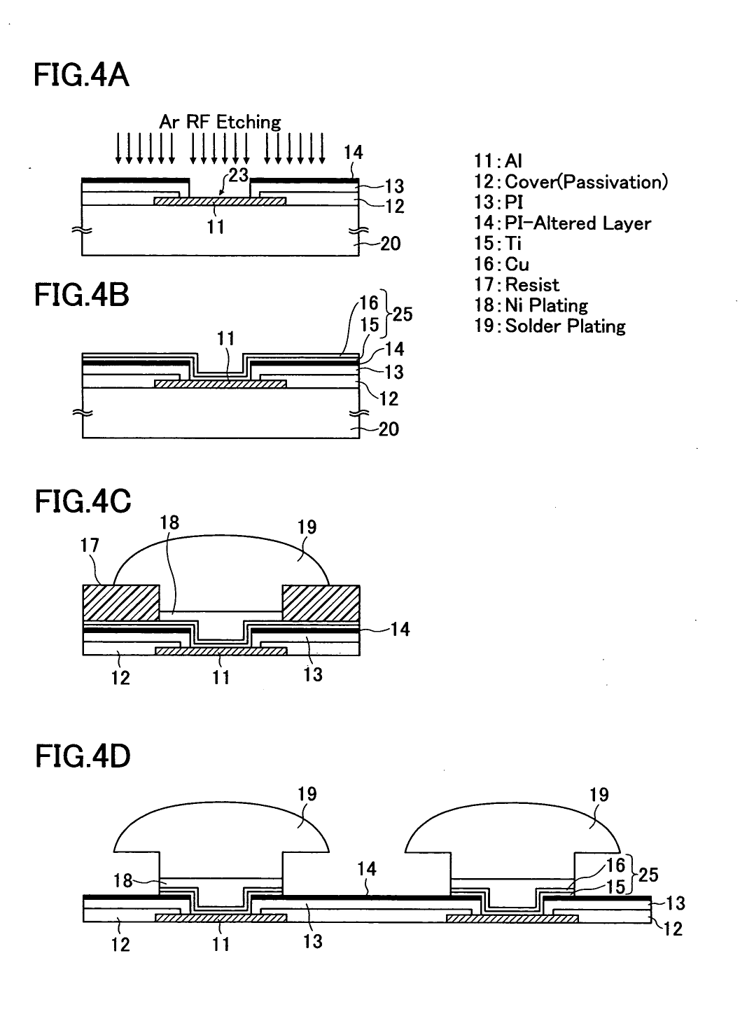

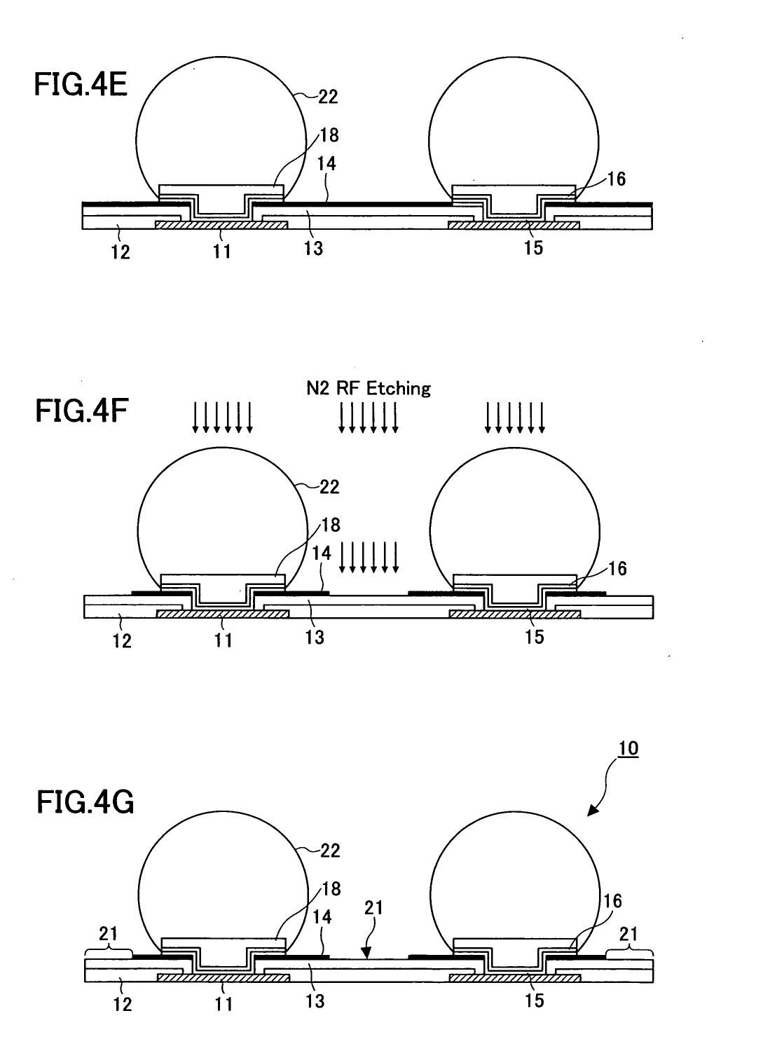

FIG. 4A through FIG. 4G illustrate a modification of the semiconductor device fabrication process of the first embodiment. The steps shown in FIG. 4A through FIG. 4D are the same as those shown in FIG. 3A through FIG. 3D, and accordingly, explanation for them is omitted.

In FIG. 4E, reflow treatment is performed to form a solder bump 22 after the step of FIG. 4D, in which the unnecessary resist 17 and seed layer 25 are removed.

Then, as illustrated in FIG. 4F, the altered layer 14 is removed from the region extending between adjacent solder bumps 22 by nitrogen (N2) etching, using an etching/ashing apparatus (not shown) equipped with an RF power source of 13.56 MHz. The dry etching is performed for 60 seconds at power of 200 W, under the nitrogen (N2) gas supply of 500 sccm at gas pressure of 40 Pa. After the removal of the altered layer 14, the resistance is restored up to 1.0*10¹¹ Ω or higher.

Then, as illustrated in FIG. 4G, reflow treatment is again performed to purge the surface of the solder bumps 22. The reflow treatment shown in FIG. 4G is optional, and it may not be performed as long as the assembling property is not damaged. In general, the fabrication process may be terminated in the step of FIG. 4F because oxygen-free RF etching is employed to remove the altered layer 14, and therefore the surface of the bump 22 is maintained substantially clear.

This modification can achieve the same advantages as those described in conjunction with the process shown in FIG. 3A through FIG. 3F.

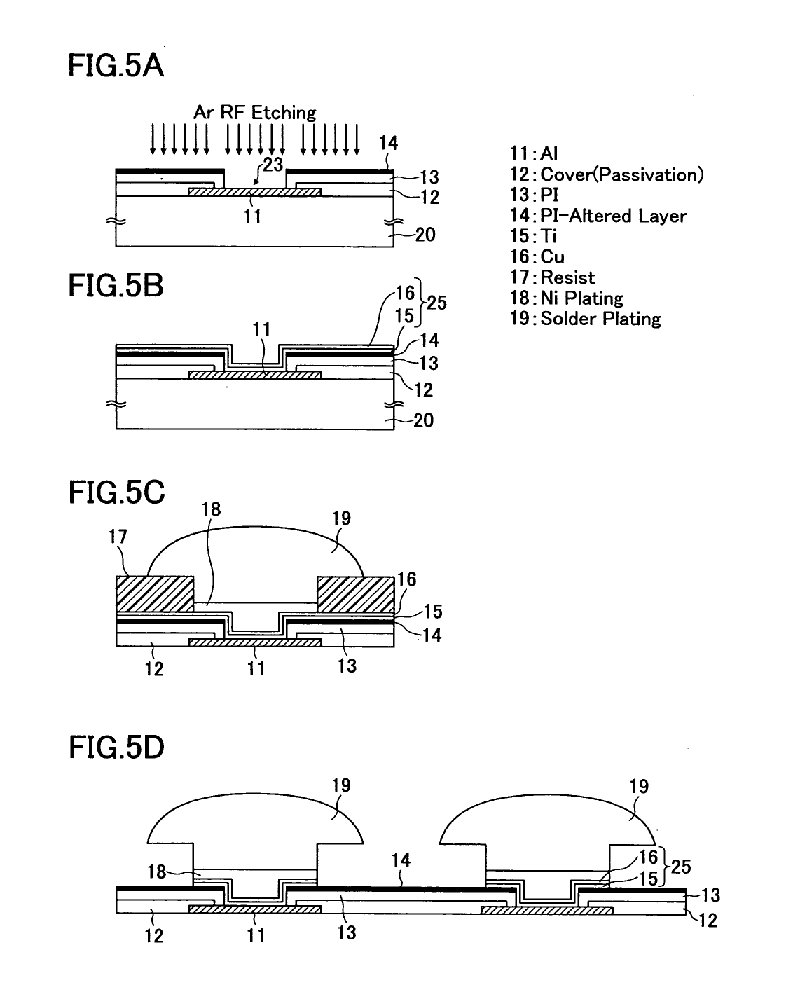

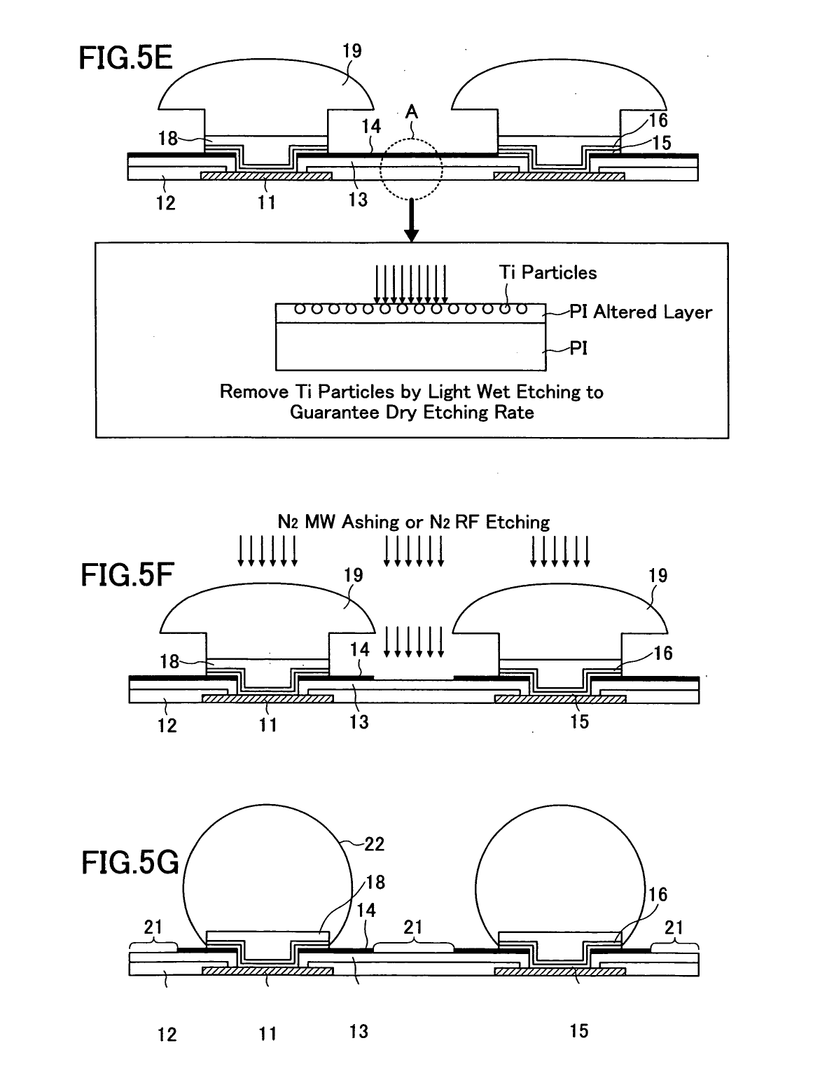

FIG. 5A through FIG. 5G illustrate a semiconductor device fabrication process according to the second embodiment of the invention. In the second embodiment, prior to the dry process for removing the altered layer 14, titanium (Ti) particles implanted into the polyimide (including the altered layer 14) during the sputtering of the Ti film 15 (the bottom layer of the seed layer 25) are removed from the altered layer 14 by light wet etching because the Ti particles hinder the ashing process.

The steps shown in FIG. 5A through FIG. 5D are the same as those shown in FIG. 3A through FIG. 3D. Namely, the native oxide layer is removed from the aluminum (Al) pad 11 exposed in the opening 23 by RF etching using argon (Ar) gas. A seed layer 25 consisting of a titanium (Ti) film 15 and a copper (Cu) film 16 is formed. Using a resist 17 with a prescribed opening pattern, nickel (Ni) plating and solder plating are carried out successively. Then, the resist 17 and unnecessary portions of the Cu film 16 and the Ti film 15 are removed.

Then, as illustrated in FIG. 5E, light wet etching is performed using 0.5% hydrofluoric (HF) acid to remove the titanium (Ti) particles implanted into the surface area of the polyimide (including the altered layer 14). This wet process guarantees the dry etching rate in the subsequent step.

Then, as illustrated in FIG. 5F, RE etching using nitrogen (N2) gas is carried out, or alternatively, an ashing process is carried out using an existing microwave (MW) asher under nitrogen (N2) gas supply. The dry process for removing the altered layer 14 using an existing microwave (MW) asher is referred as “MW ashing” for convenience purposes.

In employing RF etching, the etching conditions may be the same as those set in the first embodiment. The RE power may be set lower because the titanium (Ti) particles have already been removed. When an existing MW asher is used, three sets of N2 ashing are repeated, each set being carried out for 60 seconds at power of 1500 W and temperature of 150° C. under nitrogen (N2) gas supply of 500 sccm to 1000 sccm at gas pressure of 0.6 torr. After this dry process, the resistance level of the polyimide layer 13 is restored to 1.0*10¹¹ Ω or higher.

Finally, as illustrated in FIG. 5G, reflow treatment is performed to form a bump 22, and a semiconductor device 10 is completed. Since adjacent bumps 22 are electrically separated from each other by the altered layer removed region 21, junction leakage is reduced and operational reliability is improved. Although not shown in the figures, the top face of the polyimide layer 13 is slightly overetched at a depth of 10 nm to 20 nm in the altered layer removed region 21.

In the second embodiment, a wet process is carried out, prior to the dry process, to remove the titanium (Ti) particles implanted in the altered layer 14. This arrangement allows existing microwave (MW) ashers to be used for the removal of the altered layer. However, it is desired to employ RF etching even when the dry process is combined with the wet process, taking into account the overetch depth and the surface degradation (such as tarnish) of the polyimide layer 13.

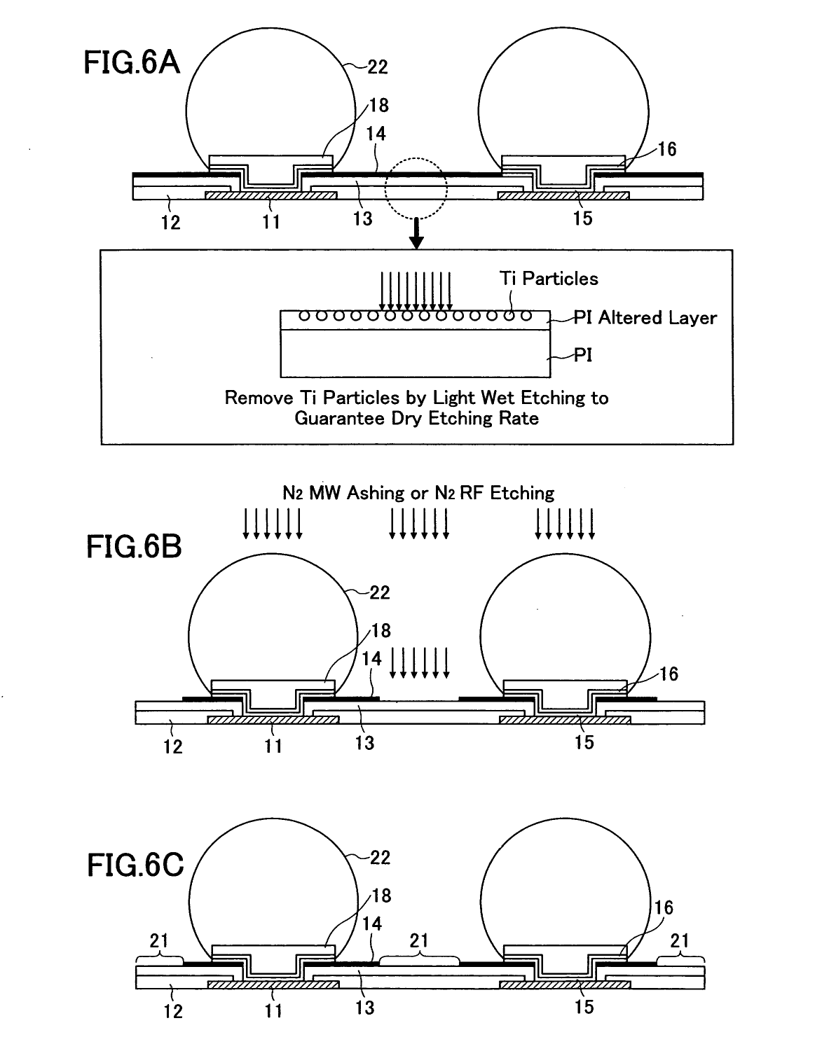

FIG. 6A though FIG. 6C illustrate a modification of the semiconductor device fabrication process of the second embodiment. The step shown in FIG. 6A follows the step shown in FIG. SD.

In FIG. 6A, reflow treatment is carried out after the unnecessary portions of the Cu film 16 and the Ti film 15 have been removed, thereby forming a bump or protruding electrode 22. After the reflow, light wet etching is performed using 0.5% hydrofluoric (HF) acid to remove the titanium (Ti) particles implanted into the altered layer 14. By performing light wet etching after the reflow, side etch of the titanium (Ti) film 15 can be prevented because the solder plating layer 19 is deformed by the reflow treatment so as to surround the titanium (Ti) film 15 under the bump 22.

Then, as illustrated in FIG. 6B, the altered layer 14 is removed by RF etching using nitrogen (N2) gas or microwave (MW) ashing under nitrogen gas supply using an existing MW asher.

Then, as illustrated in FIG. 6C, reflow treatment is performed again to purge the surface of the bump 22. This step is optional, and it may not be performed especially when N2 RF etching is employed to remove the altered layer 14.

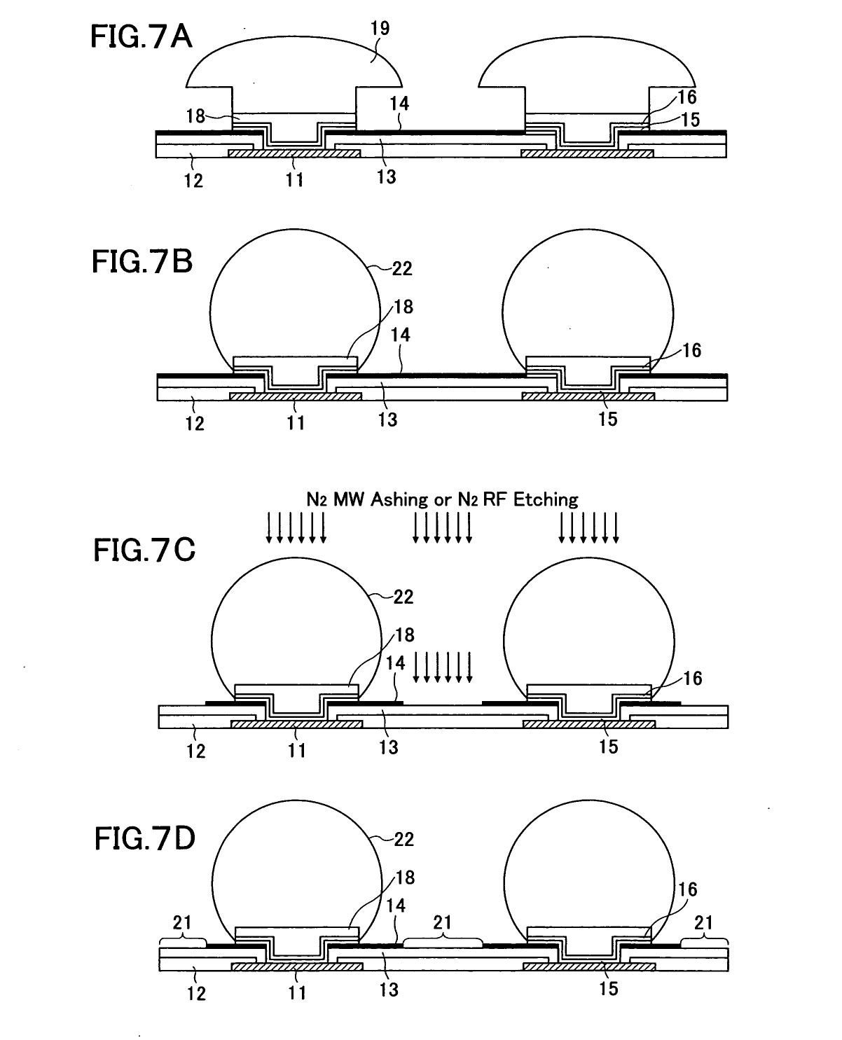

FIG. 7A through FIG. 7D illustrate another modification of the semiconductor device fabrication process of the second embodiment. In this modification, light wet etching is performed after the unnecessary portion of the seed layer is removed, and after that, reflow treatment is performed. Then, the altered layer is removed by N2 RF etching or N2 MW ashing.

The step illustrated in FIG. 7A follows the step shown in FIG. 5D. In FIG. 7A, unnecessary portions of the copper (Cu) film 16 and the titanium (Ti) film 15, which form the seed layer 25, are removed by wet etching, and successively, the titanium (Ti) particles implanted into the altered layer 14 are removed by the light wet etching. This arrangement is advantageous in that the wet processes can be performed successively, and that the dissolution of copper (Cu) due to the Ti etchant can be prevented.

Then, as illustrated in FIG. 7B, reflow treatment is performed to form a bump (or protruding electrode) 22.

Then, as illustrated in FIG. 7C, the altered layer 14 is removed by RF etching under nitrogen (N2) gas supply or microwave ashing using an existing MW asher under nitrogen (N2) gas supply.

The process may terminated at this point of time, or alternatively, reflow treatment is performed optionally to purge the surface of the bump 22, as illustrated in FIG. 7D.

In either modification, the altered layer 14 extending between adjacent bumps 22 can be removed in a reliable manner by combining a light wet process and an oxygen-free dry process.

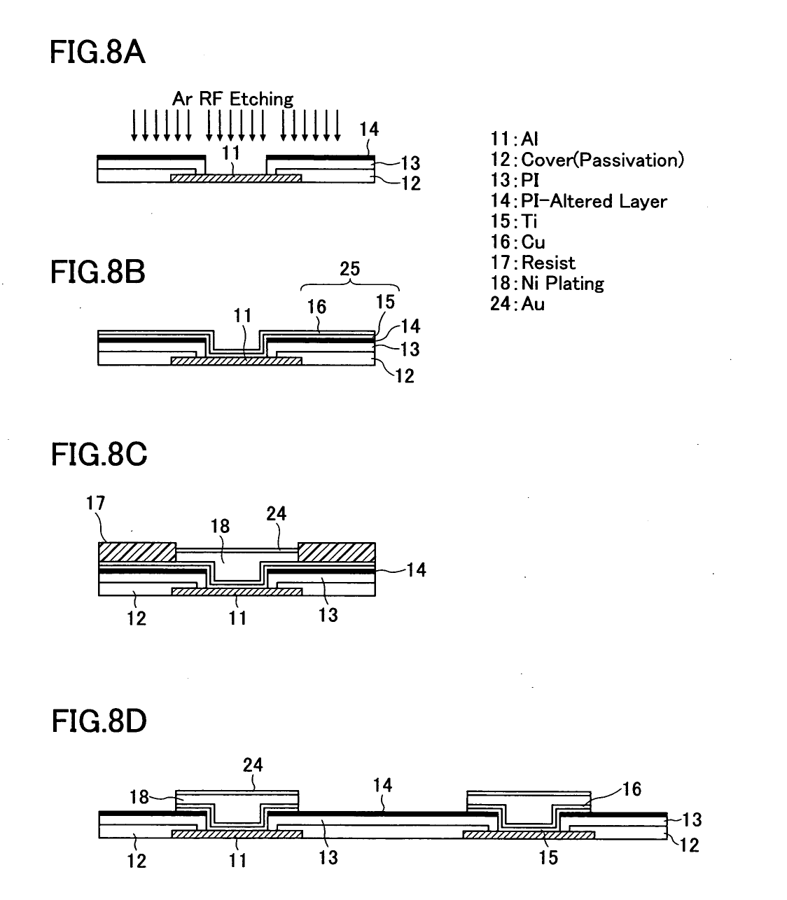

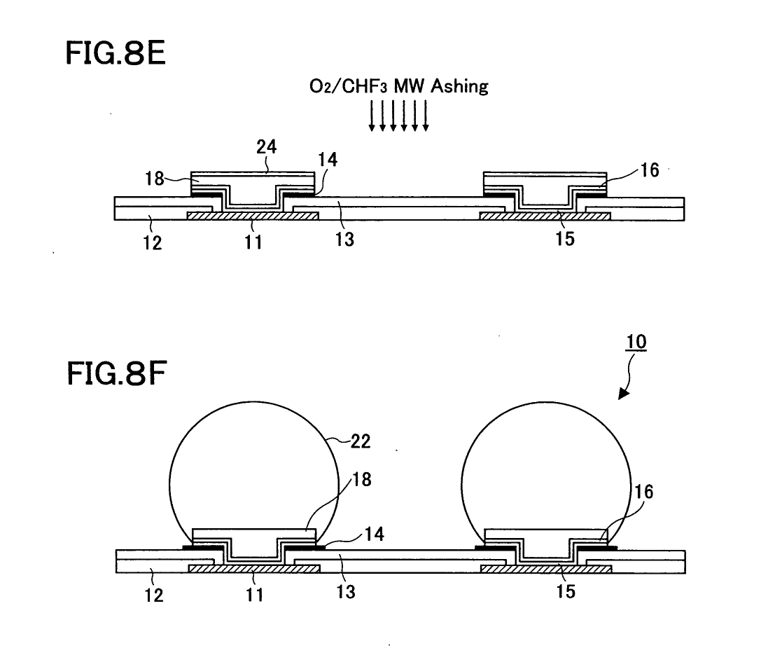

FIG. 8A through FIG. 8F illustrate a semiconductor device fabrication process according to the third embodiment of the invention. In the third embodiment, the altered layer 14 is removed by a dry process after under bump metallization (UBM).

As illustrated in FIG. 8A, the native oxide layer is removed from the exposed surface of the aluminum (Al) pad 11 by RF etching using argon (Ar) gas. In this figure, the semiconductor wafer on which the aluminum pad 11 is formed is omitted for convenience sake. The native oxide removal etching causes the surface area of the polyimide film 13 to be altered.

Then, as illustrated in FIG. 8B, a titanium (Ti) film 15 and a copper (Cu) film 16 are sputtered successively to form a seed layer 25.

Then, as illustrated in FIG. 8C, a resist 17 having an opening pattern at a position corresponding to the aluminum pad 11 is formed. Using the resist pattern 17, nickel (Ni) plating and gold (Au) plating are performed successively to form a Ni plating layer 18 and an Au plating layer 24 for under bump metallization (UBM).

Then, as illustrated in FIG. 8D, the resist pattern 17 is removed, and unnecessary portions of the Cu film 16 and the Ti film 15 are removed using the Ni plating layer 18 as a mask.

Then, as illustrated in FIG. 8E, the altered layer 14 is removed by RF etching using a gas, such as N2, N2-H2, He, H2, and Ne. The altered layer 14 is removed after the under bump metallization, and in this case, it is unnecessary to introduce the plasma into a narrow gap between bumps. To this end, an existing microwave (MW) asher may be used to perform MW ashing, in place of oxygen-free RF etching. When using a MW asher, N2, N2-H2, He, H2, Ne, and oxygen-mixed gas may be used.

As an example of the oxgen-mixed gas, CHF3/O2 gas may be used. In this case, ashing is carried out for 30 seconds under the conditions of power of 1000 W, the stage temperature of 150° C., gas pressure of 0.6 torr, and the gas flow of 15/485 sccm. When oxygen (O2) gas or another type of oxygen-mixed gas, such as O2/CF4 or O2/SF4 is used in this MW ashing, the surface of the polyimide layer 13 is degraded, causing tarnish, before a prescribed amount of etching is performed.

Finally, as illustrated in FIG. 8F, a bump (protruding electrode) 22 is formed using a printing method to complete the semiconductor device 10.

In the third embodiment, the altered layer 14 is removed following the under bump metallization, and therefore an existing microwave (MW) asher can be utilized. By providing the gold (Au) thin film on the top of the UBM, certain types of oxygen-mixed gas may be used for the microwave ashing. However, using oxygen-free etching gas is preferable from the viewpoint of preventing oxidation on the side edge of the nickel (Ni) plating layer 18.

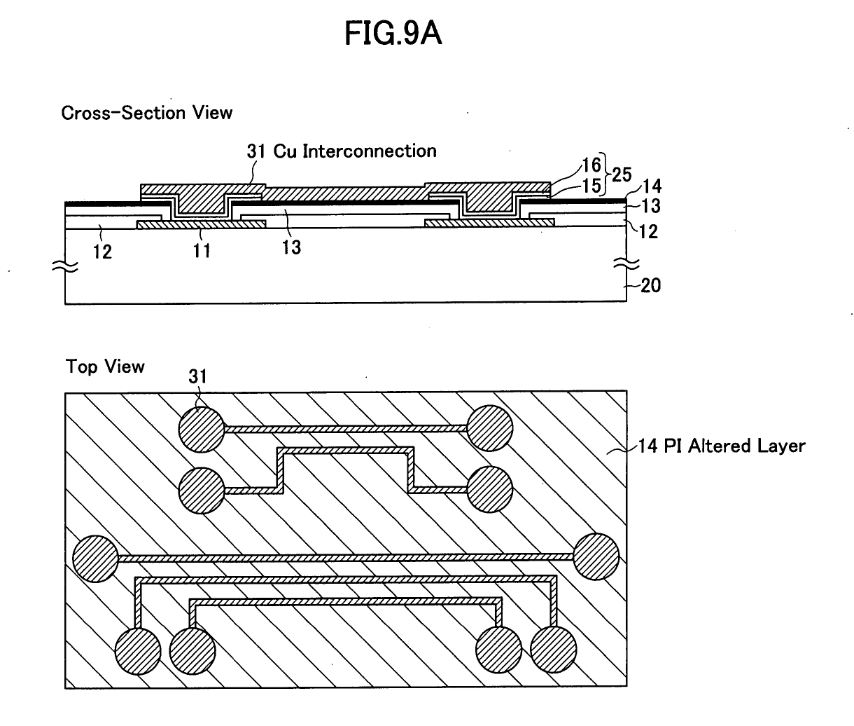

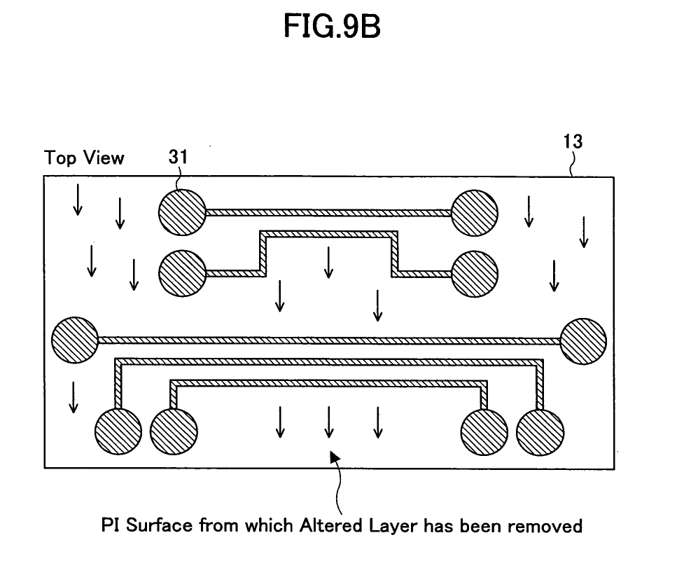

FIG. 9A and FIG. 9B illustrate a semiconductor device fabrication process according to the fourth embodiment of the invention. In the fourth embodiment, removal of an altered layer is applied to the formation of a copper (Cu) interconnection on a redistribution layer (RDL).

FIG. 9A includes a cross-sectional view and a top view of a redistribution layer in which a copper (Cu) interconnection 31 is formed with the altered layer 14 remaining on the wafer.

Prior to forming the copper (Cu) interconnection 31, an aluminum (Al) pad 11 connected to an internal electrode (not shown) is formed on the semiconductor wafer 20 having a prescribed circuit (not shown) covered with interlevel dielectrics. A passivation (cover) film 12 is formed over the aluminum (Al) pad 11 and the entire surface of the semiconductor wafer 20. An opening is formed in the passivation film 12 at a prescribed position so as to expose the top face of the aluminum (Al) pad 11. Then a polyimide film (organic coat) 13 is formed over the exposed aluminum pad 11 and the passivation film 12. The polyimide film 13 is etched to form an opening 23 at a prescribed position so as to expose the top face of the aluminum (Al) pad 11. The exposed surface of the aluminum (Al) pad 11 is pretreated by dry etching for removing the native oxide layer (not shown). During the dry etching, the surface area of the polyimide film 13 is altered and an altered layer 14 is produced. The altered layer 14 serves as a leakage layer with the resistance level reduced as low as 1.0*10⁴ Ω.

Then, a titanium (Ti) film 15 and a copper (Cu) film 16 are sputtered successively to form a seed layer 25. A resist pattern (not shown) is formed to perform copper (Cu) plating to form a copper interconnection 31. The resist is removed, and unnecessary portions of the copper film 16 and the titanium film 15 are removed.

Then, as illustrated in FIG. 9B, the altered layer 14 is removed by RF etching using an oxygen-free gas, such as N2, N2-H2, He, H2, or Ne. In the fourth embodiment, the altered layer 14 is removed from a relatively wide area extending between copper (Cu) interconnections 31. Accordingly, an existing microwave (MW) asher may be used, in place of performing RF etching. In this case, N2, N2-H2, He, H2, Ne, and oxygen-mixed gas may be used.

As an example of the oxgen-mixed gas, CF4/O2 gas may be used. In this case, two sets of ashing processes are performed, each set being carried out for 30 seconds under the conditions of power of 1000 W, the stage temperature of 150° C., gas pressure of 0.6 torr, and the gas flow of 4/196 sccm. From the viewpoint of preventing surface oxidization of the copper (Cu) interconnection 31, as well as preventing excessive amounts of overetch and surface degradation of the polyimide film 13, it is preferable to employ oxygen-free RF etching for removing the altered layer 14.

As has been described above, in any of the first through fourth embodiments, the altered layer produced in the surface area of the polyimide film can be removed efficiently by oxygen-free RF etching.

Depending on the situation, an existing microwave (MW) asher may be used. In order to maintain the surface condition of the polyimide film good and guarantee the satisfactory assembling property, RF etching is desirable.

The organic coat is not limited to polyimide, and a phenol resin may be used. The same effect applies, and the altered layer can be removed efficiently by an oxygen-free dry process.

This patent application is based on and claims the benefit of the earlier filing date of Japanese Patent Application No. 2005-033548 filed Feb. 9, 2005, the entire contents of which are incorporated herein by reference.

What is claimed is:

1. A semiconductor device comprising:
a pad electrode arranged at a prescribed position on a semiconductor wafer;
an organic dielectric film that covers the semiconductor wafer, leaving a center portion of the pad electrode uncovered;
an altered layer located in the surface area of the organic dielectric film; and
a conductor connected to the pad electrode; wherein an altered layer removed region is provided so as to separate the conductor from an adjacent one, and the organic dielectric film is overetched in the altered layer removed region to an overetch depth of 10 nm to 100 nm.

2. The semiconductor device of claim 1, wherein the conductor is a protruding electrode for device mounting, and the gap between adjacent protruding electrodes is 2 μm to 100 μm.

3. The semiconductor device of claim 1, wherein the conductor is a protruding electrode for device mounting, and the height of the protruding electrode is 5 μm to 120 μm.

4. The semiconductor device of claim 1, wherein the conductor is a metal interconnection of a redistribution layer.

5. A method for fabricating a semiconductor device, comprising the steps of:
forming a pad electrode on the semiconductor device;
coating the surface of the semiconductor device with an organic dielectric film so as to expose the center portion of the pad electrode;
treating the exposed surface of the pad electrode by dry etching; and
removing an altered layer produced in the organic dielectric film due to the dry etching for the surface treatment, using an oxygen-free dry process.

6. The method of claim 5, wherein the oxygen-free dry process is radio frequency (RF) plasma etching under oxygen-free gas supply.

7. The method of claim 6, wherein the RF plasma etching is performed at power of 400 W or lower, and temperature at or below the melting point of solder.

8. The method of claim 5, further comprising the step of:
performing light wet etching on the surface of the altered layer prior to the oxygen-free dry process;
wherein the oxygen-free dry process is dry etching or ashing under oxygen-free gas supply.

9. The method of claim 8, further comprising the step of:
forming a seed layer on the pad electrode; wherein the light wet etching uses an etchant for removing metal particles of the seed layer implanted into the altered layer.

10. The method of claim 5, wherein the oxygen-free gas includes N2, H2, Ne, He, and combination thereof.

11. The method of claim 5, further comprising the step of:
forming a protruding electrode on the pad electrode;
wherein the altered layer is removed after the protruding electrode is formed.

12. The method of claim 11, further comprising the step of:
performing a reflow treatment on the protruding electrode;
wherein the altered layer is removed before the reflow treatment.

13. The method of claim 11, further comprising the step of:
performing a reflow treatment on the protruding electrode,
wherein the altered layer is removed after the reflow treatment.

14. The method of claim 13, further comprising the step of:
performing a second reflow treatment on the protruding electrode after the removal of the altered layer.

15. The method of claim 5, further comprising the step of:
forming a protruding electrode on the pad electrode;
wherein the altered layer is removed before the protruding electrode is formed.

16. The method of claim 5, further comprising the step of:
forming a redistribution metal interconnection on the pad electrode;
wherein the altered layer is removed after the formation of the metal interconnection.

17. The method of claim 5, further comprising the step of:
performing light wet etching on the surface of the altered layer prior to the oxygen-free dry process;
wherein the altered layer is removed by radio frequency plasma or microwave plasma.

18. A method for fabricating a semiconductor device, comprising the steps of:
forming a pad electrode on the semiconductor device;
coating the surface of the semiconductor device with an organic dielectric film so as to expose the center portion of the pad electrode;
treating the exposed surface of the pad electrode by dry etching; and
removing an altered layer produced in the organic dielectric film due to the dry etching for the surface treatment, using an oxygen-mixed gas; and
forming a conductor on the pad electrode.

19. The method of claim 18, further comprising the step of:
forming a protruding electrode on the pad electrode after the removal of the altered layer;
wherein the oxygen-mixed gas is CHF3/O2.

20. The method of claim 18, further comprising the step of:
forming a redistribution metal interconnection on the pad electrode before the altered layer is removed;
wherein the oxygen-mixed gas is CF4/O2.
